(19) United States
(12) Patent Application Publication
(10) Pub. No.: US 2018/0135157 A1
(43) Pub. Date: May 17, 2018

(54) PLASMA RESISTANT COATING FILM AND FABRICATING METHOD THEREOF

(71) Applicant: KOMICO LTD., Anseong-si (KR)

(72) Inventors: Jae Hyeon JEONG, Anseong-si (KR); Jeong Min YANG, Cheongju-si (KR); Jae Ho BYUN, Cheonan-si (KR); Hyunchul KO, Anseong-si (KR)

(21) Appl. No.: 15/572,545

(22) PCT Filed: Dec. 28, 2016
(86) PCT No.: PCT/KR2016/015376

§ 371 Date: Nov. 8, 2017

(30) Foreign Application Priority Data
Dec. 31, 2015 (KR) 10-2015-0191355

(51) Int. Cl. C23C 4/06; C23C 4/123; C23C 4/18; C23C 16/06; C23C 16/448; C23C 16/56; C01F 17/00; B32B 15/01; B32B 33/00

(52) U.S. Cl. CPC C23C 4/06; C23C 4/123; C23C 4/18; C23C 16/06; C23C 16/4486; B32B 2305/026; C01F 17/0043; C01F 17/0062; B32B 15/01; B32B 33/00; C23C 16/56

(57) ABSTRACT

The present disclosure relates to a plasma resistant coating film and a fabricating method thereof, more particularly a plasma resistant coating film and a fabricating method thereof which can secure chemical resistance by means of, after thermally spraying the first rare earth metal compound, double sealing through aerosol deposition and hydration, thereby minimizing open channels and open pores in the coating layer and plasma corrosion resistance by means of the dense rare earth metal compound coating film.

### BACKGROUND OF THE DISCLOSURE

### Field of the Disclosure

The present disclosure relates to a plasma resistant coating film and a fabricating method thereof, more particularly a plasma resistant coating film and a fabricating method thereof applied to semiconductor fabricating processes including semiconductor etching equipment.

### Description of the Background Art

In general, a chamber of the equipment used for semiconductor fabricating processes is made of ceramic bulk such as anodized aluminum alloys and alumina for the sake of electrical insulation. Recently, as corrosion resistance is increasingly necessary to the high corrosive gas or plasma used for semiconductor fabricating processes such as deposition equipment using chemical vapor deposition, CVD, and others or etching equipment using plasma etching and others, the chamber is fabricated by means of plasma spray or thermal spray of ceramics such as alumina and others or by compacting then sintering such ceramics on the aluminum alloys in order to obtain high corrosion resistance.

Since high-temperature processing such as heat treatment, chemical vapor film growth and others accounts for the majority of the semiconductor fabricating processes carried out in the chamber, the chamber is also required to have heat resistance. In other words, it is necessary that parts of the semiconductor fabricating processes such as the chambers should have electrical insulation, heat resistance, corrosion resistance and plasma resistance and peel off none of the coating layer by retaining high binding force between the coating layer and the matrix, thereby minimizing any particle production during the fabricating processes and wafer pollution caused by such particles. To achieve such purposes, CVD, physical vapor deposition or sputtering have been applied as ordinarily used methods. However, they lack economic feasibility including an excessively long processing time to grow a thick film to an extent which meets the requirements such as corrosion resistance and others while it is also difficult to develop high binding force between the coating layer and the matrix because they are thin film fabricating processes.

Although plasma spray or thermal spray, which are mostly used for growing a thick film, apart from the above methods, have a merit of developing a thick film, such hot processes have demerits of lowering the binding force between metal and ceramic due to the difference of their thermal expansion and, in some cases, producing an oxidation layer generated on melted metal matrix because they coat ceramic materials on the metallic matrix, which shows the restrictions involved in the hot processes.

Meanwhile, aerosol deposition can grow a dense thick film overcoming such problems, but it also reveals a question that it is difficult to develop a dense thick film of rare earth metal compounds of 100 μm or more. Therefore, the aerosol method might bring about a life issue of a thick film exposed to high voltage and plasma.

A method using a plasma spray process for developing a thick film of 100 μm or more is disclosed in KR2003-0077155A, but it is difficult to fabricate a dense coating film when a plasma spray process is used for developing a thick film.

As a countermeasure, KR1108692B1 describes a rare earth metal compound coating film formed on a porous ceramic layer of a substrate which includes the porous ceramic layer whose average surface roughness ranges from 0.4 to 2.3 μm in order to form a dense plasma resistant coating film which seals up the surface of the porous thick film or the porous ceramics over 100 μm. However, there is a limit to damage prevention of a coating film or improvement of electrical insulation, corrosion resistance, plasma resistance and others of the parts of semiconductor fabricating equipment because the porous ceramic layer and the rare earth metal compound show their composition different from each other bringing out inhomogeneity between the coating layers producing low binding force, it is highly possible to detect alumina composition after plasma etching of the rare earth metal compound and it is impossible to reduce porosity below 5% in that the relative density of the rare earth metal compound is 95%.

### SUMMARY OF THE DISCLOSURE

To resolve the problems, the present disclosure provides the plasma resistant coating film and the fabricating method thereof which have superior plasma resistance and electrical insulation, chemical resistance and others as well by densely sealing up a coating layer formed on an object of coating. To achieve this objective, a working example according to the present disclosure provides the fabricating method of the plasma resistant coating film which includes:

(a) a step of forming a first rare earth metal compound layer by thermally spraying a first rare earth metal compound on an object of coating;
(b) a step of forming a second rare earth metal compound layer by aerosol-depositing a second rare earth metal compound on the formed first rare earth metal compound layer; and
(c) a step of hydrating the formed first and second rare earth metal compounds.

The first rare earth metal compound of a desirable working example according to the present disclosure is one or more species selected from a group of Y₂O₃, Dy₂O₃, Er₂O₃, Sm₂O₃, YAG, YOF and YF.

The first rare earth metal compound layer of a desirable working example according to the present disclosure has a thickness of 100 to 300 μm.

The step of (c) hydrating of a desirable working example according to the present disclosure includes:

(i) washing the formed first and second rare earth metal compound layers;
(ii) drying the washed first and second rare earth metal compound layers;
(iii) wetting the dried first and second rare earth metal compound layers; and
(iv) vacuum-baking the wet first and second rare earth metal compound layers.

The wetting of a desirable working example according to the present disclosure is performed at 60 to 120° C. for 1 to 48 hours.

The hydrating of a desirable working example according to the present disclosure repeats the steps (iii) and (iv) twice or more.

The second rare earth metal compound of a desirable working example according to the present disclosure is one or more species selected from a group of Y₂O₃, Dy₂O₃, Er₂O₃, Sm₂O₃, YAG, YOF and YF.

The second rare earth metal compound coating layer of a desirable working example according to the present disclosure has a thickness of 5 to 30 μm.

The first rare earth metal compound coating layer of a desirable working example of the present disclosure has a porosity of 10 vol % or less after the step (c).

The second rare earth metal compound coating layer of a desirable working example of the present disclosure has a porosity of 5 vol % or less.

A working example of the present disclosure provides the plasma resistant coating film which includes,

the first rare earth metal compound layer which is formed according to the fabricating method of the plasma resistant coating film by thermally spraying the first rare earth metal compound and hydrating the compound; and
the second rare earth metal compound layer which is formed by aerosol-depositing the second rare earth metal compound on the first rare earth metal compound layer and hydrating the compound.

The fabricating method of the plasma resistant coating film according to the present disclosure can provide the object of coating with plasma resistance, high voltage resistance and high electrical resistance by having a stacking structure of the first rare earth metal compound layer and the second rare earth metal compound.

In addition, the fabricating method produces stable physical properties of the coating layers and increased binding force between the coating layers because the stacked first and second rare earth metal compound layers are composed of materials with the identical physical properties.

Moreover, the fabricating method of the plasma resistant coating film according to the present disclosure can be usefully applied to the components for various kinds of semiconductor equipment because the fabricating method can secure chemical resistance by means of, after thermally spraying the first rare earth metal compound, double sealing through aerosol deposition and hydration, thereby minimizing open channels and open pores in the coating layer and plasma corrosion resistance by means of the dense rare earth metal compound coating film.

### BRIEF DESCRIPTION OF THE SEVERAL VIEWS OF THE DRAWING

FIGS. 1(a) and 1(b) are a schematic view of a process of forming the plasma resistant coating film according to the present disclosure, where FIG. 1(a) illustrates the first rare earth metal compound layer formed by means of a spraying technique and FIG. 1(b) illustrates the hydrated first and second rare earth metal compound layers.

FIG. 2 is a vertical cross-sectional SEM image of the coating film fabricated in the Embodiment 1 according to the present disclosure.

FIGS. 3(a) and 3(b) show EDS analysis charts which describe the coating film before and after hydration, FIG. 3(a) and FIG. 3(b), respectively, as fabricated in the Embodiment 1 according to the present disclosure.

FIG. 4 shows XRD analysis peaks which correspond to the coating film before and after hydration, curve (a) and curve (b), respectively, as formed in the Embodiment 1 according to the present disclosure.

FIGS. 5(a) and 5(b) show ink infiltration measurement images of the coating films formed in the Embodiment 1(b) and the Comparative Example 1(a), respectively, according to the present disclosure.

### REFERENCE CHARACTERS

100: Object of coating
110: First rare earth metal compound layer
120: Second rare earth metal compound layer
150: Plasma resistant coating film

### DETAILED DESCRIPTION OF THE DISCLOSURE

Embodiments described in the present Specification and the configurations illustrated in the drawing are simple examples of the present disclosure, not entirely representing the technical thoughts of the present disclosure, and should be construed as including various equivalents and conversions which can replace them at the time of applying the present Specification. Similar reference characteristics are used for similar features for describing each of the drawings. The dimensions of the structure in the accompanying drawings are expanded from the real dimensions for ensuring the accuracy of the present disclosure and reduced for describing its schematic configuration. Terms such as a first and a second may be used for describing various features but such features should not be limited thereto. Such terms should be used only for distinguishing one feature from others. For example, within the scope of right of the present disclosure, a first feature may be named a second feature and, similarly, vice versa.

Terms in the present Specification are used just for describing specific embodiments and should not limit the present disclosure. Unless otherwise contextually signified explicitly, a singular form includes its plural forms. Such terms as “include/including”, “have/having” and others used in the present Specification are to indicate the existence of the characteristics, numbers, steps, actions, components, parts or their combination written in the present Specification and not to exclude in advance the possibilities of the existence or addition of one or more other characteristics, numbers, steps, actions, components, parts or their combination.

Unless otherwise defined, all the terms and words used in the present Specification and Claims including technical and scientific ones should have the same meanings and concepts as what a person skilled in the art to which the present disclosure belongs ordinarily understands. The meanings and concepts of the terms defined in an ordinarily used dictionary should be construed that they are identical to the contextual meanings and concepts in the related art and, unless otherwise explicitly defined in the present specification, not be construed ideally or excessively formally.

Embodiments according to the present disclosure will be described more fully hereinafter with reference to the accompanying drawings.

An aspect according to the present disclosure relates to the fabricating method of the plasma resistant coating film which includes:

(a) the step of forming the first rare earth metal compound layer by thermally spraying the first rare earth metal compound on the object of coating;
(b) the step of forming the second rare earth metal compound layer by aerosol-depositing the second rare earth metal compound on the formed first rare earth metal compound layer; and
(c) the step of hydrating the formed first and second rare earth metal compounds.

More specifically, coating layers formed on an object of coating by means of the existing spraying techniques involve open channels and open pores bringing about the possibilities of the seasoning issue due to outgassing generation from the remaining trace gas inside the coating layers and coating life reduction due to infiltration of the corrosive plasma gas inside a chamber during a semiconductor process.

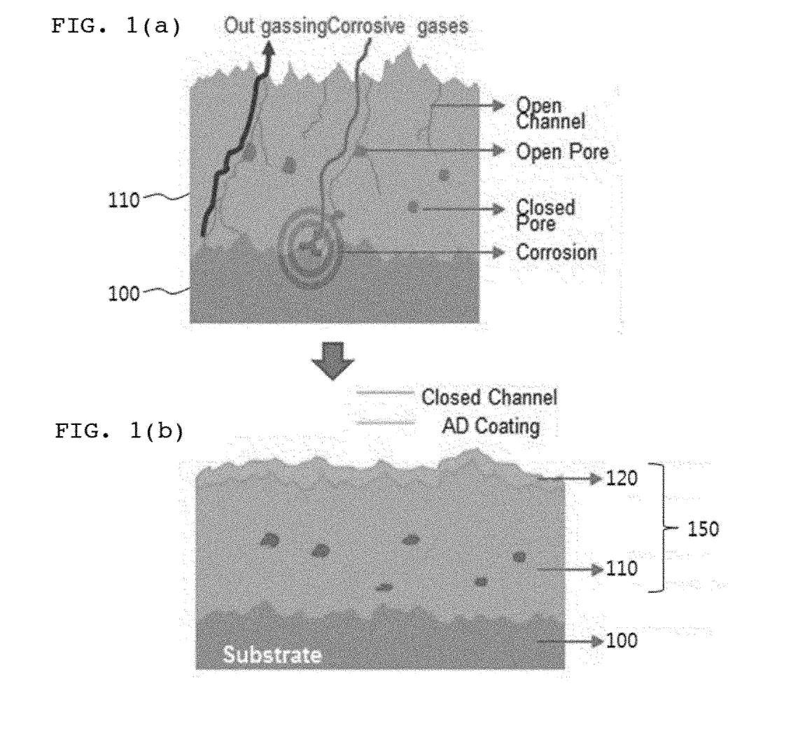

To resolve the problems, the fabricating method of plasma resistance coating film according to the present disclosure, as illustrated in FIGS. 1(a) and 1(b), comprise forming the first rare earth metal compound layer 110 by means of a spray coating technique on the object of coating 100, and first sealing up the first rare earth metal compound layer 110 by forming the second rare earth metal compound layer 120 on the first rare earth metal compound layer 110 by means of the aerosol deposition coating (AD coating) technique. Then second sealing up is applied to the first and second rare earth metal compound layer, which, in turn, improves the coating characteristics by minimizing the open channels and open pores formed in the coating layers, and retains stable chamber conditions by minimizing outgassing, resulting minimizing seasoning time and improving chemical resistance.

The fabricating method of the plasma resistant coating film according to the present disclosure includes, at first, forming the first rare earth metal compound layer 110 by thermal spraying the first rare earth metal compound, by means of the spray coating technique, on the object of coating 100 [step (a)].

The object of coating 100 on which the first rare earth metal compound layer is formed is possibly a plasma device such as electrostatic chucks, heaters, chamber liners, shower heads, boats for CVD, focus rings, wall liners and others while the object of coating 100 can be made of metals such as iron, magnesium, aluminum, their alloys and others; ceramics such as SiO2, MgO, CaCO3, alumina and others; or polymers such as polyethyleneterephthalate, polyethylenenaphthalate, polypropyleneadipate, polyisocyanate and others but not limited thereto.

In addition, the object of coating 100 can be sanded on its surface to provide a certain surface roughness and improve the adhesive characteristics between the object of coating 100 itself and the first rare earth metal compound layer 110 which is formed later.

For example, when the surface roughness of the sanded object of coating is below 1 μm, the adhesive characteristics get deteriorated between the first rare earth metal compound layer which is to be formed later and the object of coating for the first rare earth metal compound layer to easily peel off the object of coating due to external impact. In contrast, when the surface roughness of the sanded object of coating is over 8 μm, the second rare earth metal compound layer is not possibly formed to a uniform thickness on the first rare earth metal compound layer because the roughness has an influence on the surface roughness of the first rare earth metal compound layer. Therefore, the present embodiment sands the object of coating so that the object of coating has an average central surface roughness of about 1 to 8 μm.

Thermal spray coating methods can be applied to forming the first rare earth metal compound layer 110 on the object of coating in order to form the coating layer which meets the requirements such as strong binding force between the object of coating and the coating layer, corrosion resistance and others. Preferably, plasma thermal spray coating techniques can be applied taking account of high hardness and high electrical resistance of the coating layer.

In the step (a), the first rare earth metal compound layer 110 is formed by means of thermal spray-coating the first rare earth metal compound on the object of coating 100 and desirably has a thickness of 100 to 300 μm and an average central surface roughness, Ra, of 1 to 7 μm. Voltage resistance decreases when the thickness of the first rare earth metal compound layer is below 100 μm while processing time increases, thereby lowering productivity, when the thickness exceeds 300 μm.

In addition, when the surface roughness of the first rare earth metal compound layer is below 1 μm, the effect of pollutant collection is decreased, because the pollutants adsorption area of plasma resistant coating film inside the plasma etching chamber is reduced. When the surface roughness exceeds 7 μm, the second rare earth metal compound layer is not formed uniformly on the first rare earth metal compound layer.

Furthermore, it is desirable for the Rz, one of the surface roughness values of the first rare earth metal compound layer to have 30 to 50. When an Rz value measured after the first rare earth metal compound layer is formed exceeds 50, the process of brushing (polishing) and removing the surface of the un-melted particles on the first rare earth metal compound layer can be further performed. Rz values which measure the surface roughness referred to in the present embodiment are calculated by means of the ten-point average roughness technique and indicate the calculated average of the highest and lowest protrusions on the surface of the first rare earth metal compound layer. The surface of the first rare earth metal compound layer can be polished taking into consideration the fact that the first rare earth metal compound layer has those protrusions that are higher than its average roughness.

Yttria (Y₂O₃), dysprosia (Dy₂O₃), erbia (Er₂O₃), samaria (Sm₂O₃), YAG, yttrium fluoride (YE), yttrium oxyfluoride (YOF), and others can be used as the first rare earth metal compound.

The first rare earth metal compound which constitutes the first rare earth metal compound layer has strong resistance to plasma. Hence, it gives the corrosion resistance and voltage resistance against the plasma of semiconductor processes when the compound is applied to the parts of semiconductor equipment such as semiconductor etching equipment which requires corrosion resistance. The second rare earth metal compound layer 120, which is deposition of the second rare earth metal compound by means of the AD coating technique, is formed on the first rare earth metal compound layer 110 in order to firstly sealing up the first rare earth metal compound layer by forming a further coating layer [step (b)].

The second rare earth metal compound layer 120 formed by means of the AD coating technique on the first rare earth metal compound layer is a high-density rare earth metal compound layer of which pore content is 10 vol % or less and has a thickness of 5 to 30 μm and an average central surface roughness of 01. to 3.0 μm.

A thickness less than 5 μm of the second rare earth metal compound layer is too thin to obtain plasma resistance in a plasma environment while a thickness over 30 μm causes coating layer detachment due to residual stress in the coating layer, possibilities of detachment also during processes and economic loss due to excessive use of the rare earth metal compound.

In addition, when the surface roughness of the second rare earth metal compound layer is below 0.1 μm, the effect of pollutant collection is decreased, because the pollutants adsorption area of plasma resistant coating film inside the plasma etching chamber is reduced. When the surface roughness exceeds 3.0 μm, the second rare earth metal compound layer is not formed uniformly.

Moreover, when the second rare earth metal compound layer has a pore content over 10 vol %, the mechanical strength of plasma resistant coating film which is to be finally formed is decreased.

Therefore, in order to secure mechanical strength and electrical properties of the plasma resistant coating film, the second rare earth metal compound layer can desirably contain 0.01 to 5 vol % of pores.

According to an embodiment of the present disclosure, the aerosol deposition for forming the second rare earth metal compound layer includes inputting particles of the rare earth metal compound whose grain size is 10 μm or less inside an aerosol chamber and placing the object of coating inside a deposition chamber. The second rare earth metal compound particles are supplied to the aerosol chamber and injected into the aerosol chamber with Ar gas to be aerosolized. Apart from Ar, inert gases such as compressed air, H₂, He, N₂ or others can be selected as the carrier gas. Due to the pressure difference between the aerosol chamber and the deposition chamber, the second rare earth metal compound particles are, together with the carrier gas, inhaled into the deposition chamber and sprayed at high speed through a nozzle toward the object of coating. Resulting from the spraying the second rare earth metal compound is deposited, thereby forming the highly dense second rare earth metal compound layer. The area on which the second rare earth metal compound is deposited is controlled as intended by moving the nozzle from side to side while its thickness is also determined in proportion to the deposition time, or spraying time.

By aerosol deposition of the second rare earth metal compound, the second rare earth metal compound layer 120 can be repeatedly formed twice or more.

The rare earth metal compound of the second rare earth metal compound layer can be identical to the second rare earth metal compound layer or selected from a rare earth metal compound with other component. For example, Y₂O₃, Dy₂O₃, Er₂O₃, Sm₂O₃, YAG, YF, YOF and others can be used.

The second rare earth metal compound layer 120, as a thick film of the first rare earth metal compound layer 110, is made of those constituents which have physical properties identical to those of the first rare earth metal compound layer having high resistance to the plasma to which the layer is exposed during semiconductor processes and strong binding force with the first rare earth metal compound layer, thereby producing no peeling of the coating layer, thereby minimizing particle generation and wafer pollution during the production processes.

It is desirable to use compressed air of medical grade during the AD coating process. The compressed air of medical grade prevents the compound from not being aerosolized due to moisture contained in the ordinary air and also prevents any impurities such as oil in the air being captured in the film during the AD coating.

In addition, when peeling off the coating film and re-coating is required due to a plasma resistant part is polluted with pollutants during a plasma process, the second rare earth metal compound layer as a highly dense coating film is detached with a blasting process and the second rare earth metal compound layer is formed again by AD coating.

As described above, after the second rare earth metal compound layer is formed on the first rare earth metal compound layer, the first and second rare earth metal compound layers are hydrated secondly sealing up the open channels and open pores contained in the coating layers [step (c)].

In hydrating the layers, the first and second rare earth metal compound layers are washed [step (i)]; the washed first and second rare earth metal compound layers are dried[step (ii)]; the dried first and second rare earth metal compound layers are wetted[step (iii)]; and the first and second rare earth metal compound layers are vacuum-baked.

In the step (i) of the hydration, the layers can be washed using a cleaning agent such as alcohol, deionized water, acetone, surfactants and others in order to remove foreign objects, impurities and others which adhere to the second rare earth metal compound layer.

In the step (ii) of the hydration, the washed first and second rare earth metal compound layers are dried at 60 to 120° C. for 1 to 48 hours. When the drying conditions go beyond the ranges, effects of the wetting might be weakened due to the open pores and residual moisture in cracks or productivity might be reduced due to increase in processing time.

In the step (iii) of the hydration, the wetting treatment is to fill in the open pores, cracks and others formed in the first and second rare earth metal compound layers by impregnating water into the pores and fine cracks in the dried first and second rare earth metal compound layers in order to form hydroxide in the pores and fine cracks in the first and second rare earth metal compound layers by means of the reaction of the impregnated water with the first and second rare earth metal compounds.

Any method to infiltrate water into the first and second rare earth metal compound layers without restrictions can be applied for the wetting treatment. For example, deionized water can be sprayed using a sprayer onto the second rare earth metal compound layer to impregnate the water into the first and second rare earth metal compound layers or the object of coating on which the first and second rare earth metal compound layers are form can be submerged in the water for wetting the first and second rare earth metal compound layers.

Here, the wetting treatment can be carried out under the ambient pressure, at 60 to 120° C. for 1 to 48 hours. When the temperature of the wetting treatment is below 60° C., it is difficult for water to impregnate into the coating layers while, when the temperature is over 120° C., water might infiltrate into the coating layers to an excessive extent or up to the object of coating. Likewise, when the wetting time is below 1 hour, it is difficult for water to infiltrate into the coating layers while, when it exceeds 48 hours, water might impregnate into the coating layers to an excessive extent or up to the object of coating.

When any water other than the deionized water is used for the wetting treatment, the ions contained in the water can have an influence on the coating layers. A pH value below about 6 or over 8 can damage the coating layers, which means the pH value of the water is desirably 6 to 8.

In the step (iv) of the hydration, the vacuum baking treatment can be carried out under a pressure of 10⁻² to 10⁻⁴ mTorr at 60 to 120° C. for 1 to 48 hours in order to remove residual moisture contained in the wet first and second rare earth metal compound layers. When the temperature of the vacuum baking treatment is below 60° C., the second rare earth metal compound layer gets reluctant to react with moisture, thereby reducing hydroxide formation efficiency while, when it exceeds 120° C., damage might occurs including crack formation in the coating layers or detachment of the coating layers.

When the heating time is below 1 hour, the coating layers might not sufficiently react with moisture while, when it exceeds 48 hours, productivity might be decreased due to increased processing time.

For example, when the first and second rare earth metal compound layers are yttrium oxide, Y₂O₃, the yttrium oxide reacts with moisture to form yttrium hydroxide, Y(OH)₃. In this way, the open channels contained inside the first and second rare earth metal compound layers are tightly filled in by hydrating the first and second rare earth metal compound layers because the Y₂O₃ in the crack paths inside the coating layers produces hydroxide, the product of hydration.

Here, the hydrating the first and second rare earth metal compound layers can repeatedly perform the wetting treatment and vacuum baking treatment twice or more, desirably 2 to 10 times, after the washing [step (i)] and the drying [step (ii)] in order to produce the hydroxide in sufficient quantity.

The treated first rare earth metal compound layer has a porosity of 10 vol % or less, desirably 7 vol % or less while the treated second rare earth metal compound layer has a porosity of 5 vol % or less, desirably 3 vol % or less, which fully fills in the open channels and the open pores which would, before the hydrating treatment, otherwise be contained in the first and second rare earth metal compound layers, thereby preventing the seasoning issue and life reduction of the coating layers due to corrosive plasma gas infiltration in the chamber during semiconductor processes.

An aspect according to the present disclosure relates to the plasma resistant coating film which is formed according to the fabricating method of the plasma resistant coating film by thermal spray-coating the object of coating with the first rare earth metal compound, hydrated the first rare earth metal compound layer and

AD-coating the first rare earth metal compound layer with the second rare earth metal compound and contains the hydrated second rare earth metal compound layer.

The plasma resistant coating film according to the present disclosure is a composite coating film 150 which satisfies such characteristics as plasma resistance, electrical resistance, adhesion and others altogether by including the hydrated first and second rare earth metal compound layers 110, 120 on the object of coating 100

The hydrated plasma resistant coating film 150 according to an embodiment of the present disclosure has a stacking structure of the first rare earth metal compound layer 110 formed by means of the spray coating technique, the second rare earth metal compound layer 120 formed by means of the AD coating technique.

Here, as described above, for hydrating the second rare earth metal compound layer, the first and second rare earth metal compound layers are washed; the washed first and second rare earth metal compound layers are dried; the dried first and second rare metal compound layers go through the wetting treatment; and then the first and second rare earth metal compound layers go through the vacuum-baking treatment.

Since the first rare earth metal compound layer is hydrated and the second rare earth metal compound layer is formed by means of the AD coating technique on the first rare earth metal compound layer in order to obtain a denser coating layer, the open channels and the open pores contained in the coating layers, which is characteristic of the thermal spray coating technique, are tightly filled in while the coating layers have hardness, electrical resistance and others higher than those of existing thermal spray-coated layers, which is effective in protecting the chamber and the equipment in the plasma atmosphere which is a corrosive environment. Here, the first rare earth metal compound layer has a thickness of 100 to 300 μm, an average central surface roughness, Ra, of 2 to 7 μm and a porosity of 10 vol % or less, desirably 7 vol % or less.

For example, the first rare earth metal compound layer can be a single layer of coating film which contains the rare earth metal compound formed by means of the thermal spray coating technique with the rare earth metal compound particles for spray coating. The first rare earth metal compound layer is fabricated by the particles for thermal spray coating with the mean diameter 20˜60 μm.

Meanwhile, the second rare earth metal compound layer is a highly dense coating film which is formed on the first rare earth metal compound layer by means of the AD coating technique and hydrated for having low porosity and high adhesion. The first rare earth metal compound layer increases coating film durability because its plasma damage is minimized. The second rare earth metal compound layer has a porosity of 5 vol % or less, desirably 3 vol % or less, a thickness of about 5 to 30 μm and an average central surface roughness of 0.1 to 1.5 μm.

For example, the second rare earth metal compound layer is formed by means of the AD technique using the second rare earth metal compound particles and might be the hydrated highly dense second rare earth metal compound layer.

Because the second rare earth metal compound layer is formed on the first rare earth metal compound layer, the second rare earth metal compound layer can avoid the problem that pollutants come into the thermal spray-coated first rare earth metal compound layer through the fine cracks and pores contained in the first rare earth metal compound layer to deteriorate coating film durability, thereby further improving the durability of the whole coating film.

Because plasma resistant coating film with such a structure described above has a stacking structure of the hydrated second rare earth metal compound layer and the first rare earth metal compound layer whose plasma resistance is excellent, the plasma resistant coating film can provide the object of coating with plasma resistance, high voltage resistance and high electrical resistance. With such high electrical resistance and voltage resistance, the plasma resistant coating film can prevent itself from being damaged by minimizing arcing generation when the film is exposed to a plasma process.

In addition, the plasma resistant coating film according to the present disclosure has an advantageous effect that the film is not easily detached by external impact by applying the first rare earth metal compound layer which improves adhesion characteristics between the object of coating and the highly dense second rare earth metal compound layer.

Embodiments and comparative examples according to the present disclosure will now be described more specifically hereinafter. The embodiments exemplify but should not limit the scope of right of the present disclosure.

### Embodiment 1

### 1-1: Forming the First Rare Earth Metal Compound Layer

The first rare earth metal compound layer with a thickness of 150 μm was formed by thermal spraying yttria (Y₂O₃) particles for thermal spray coating with an average grain size of 30 μm on an aluminum plate of 5 cm×5 cm×0.5 cm by using the plasma spray coating technique (He and Ar as process gas, heat source of 3000 K).

### 1-2: Forming the Second Rare Earth Metal Compound Layer

The second rare earth metal compound layer with a thickness of 10 μm was formed by aerosolizing yttria (Y₂O₃) particles by using a particle vibrator in an aerosol chamber maintained in vacuum atmosphere at ambient temperature and then physically colliding at about 300 m/s the aerosolized yttria particles together with Ar gas onto the first rare earth metal compound layer of the Embodiment 1-1 by using the pressure difference between the aerosol chamber and a deposition chamber.

### 1-3: Fabricating the Coating Film

The aluminum pate on which the second rare earth metal compound layer was formed through the Embodiment 1-2 was washed with deionized water, dried at 100° C. for 3 hours and wet by being submerged in deionized water maintained at 90° C. for 5 hours. The wetting-treated aluminum plate was dried in vacuum atmosphere at 100° C. for 5 hours. The wetting and drying in vacuum were repeated 5 times under the same conditions to form the coating film.

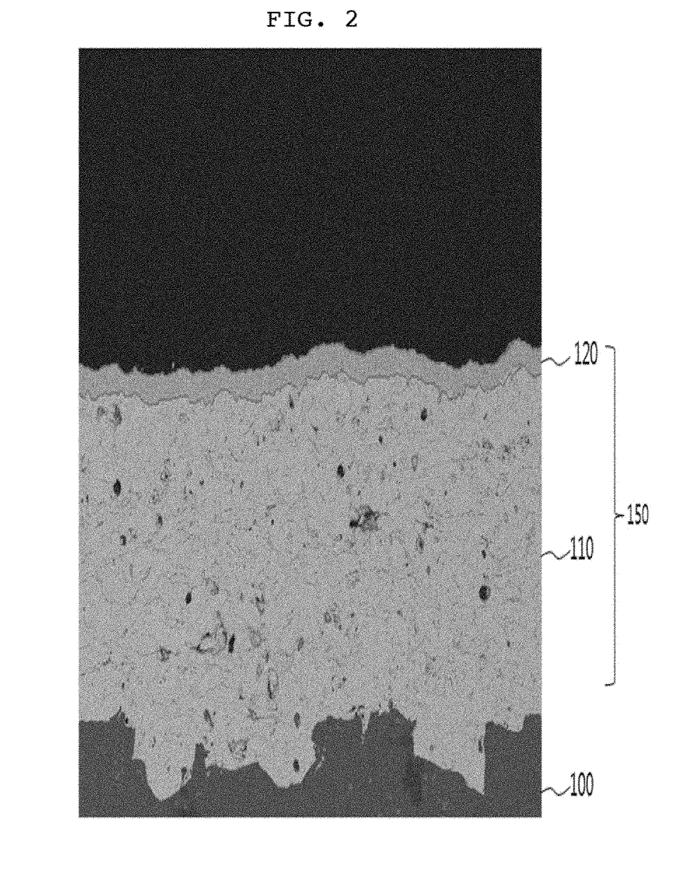

The cross-section of the formed coating film was analyzed by using an SEM (JEOL 6001) for verifying how the open pores and the open channels of the coating film were filled in. The results are shown in FIG. 2. As shown in FIG. 2, it is verified that the open channels and the open pores of the coating film fabricated in the Embodiment 1 are stably filled in.

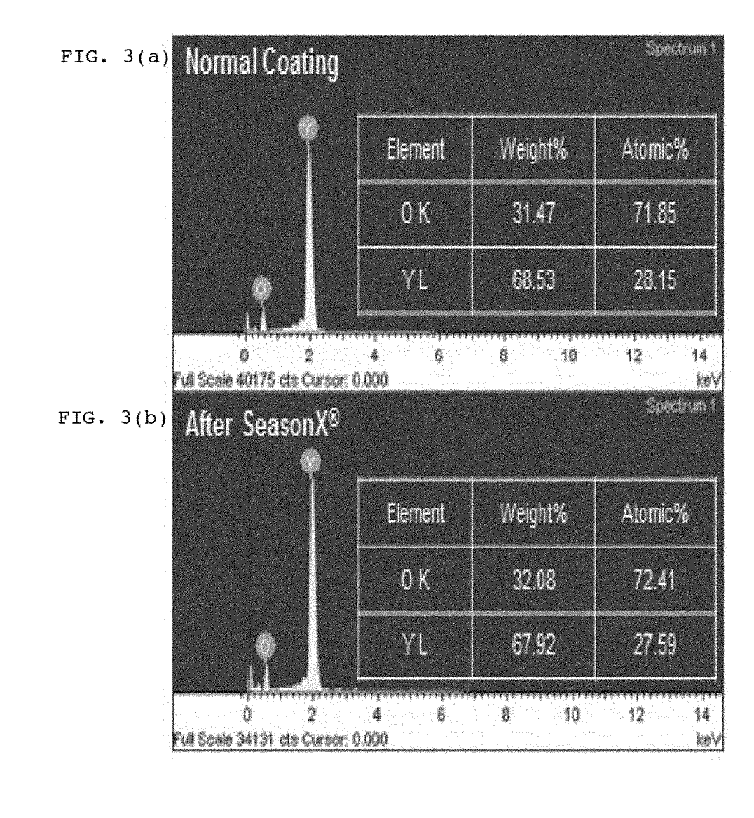

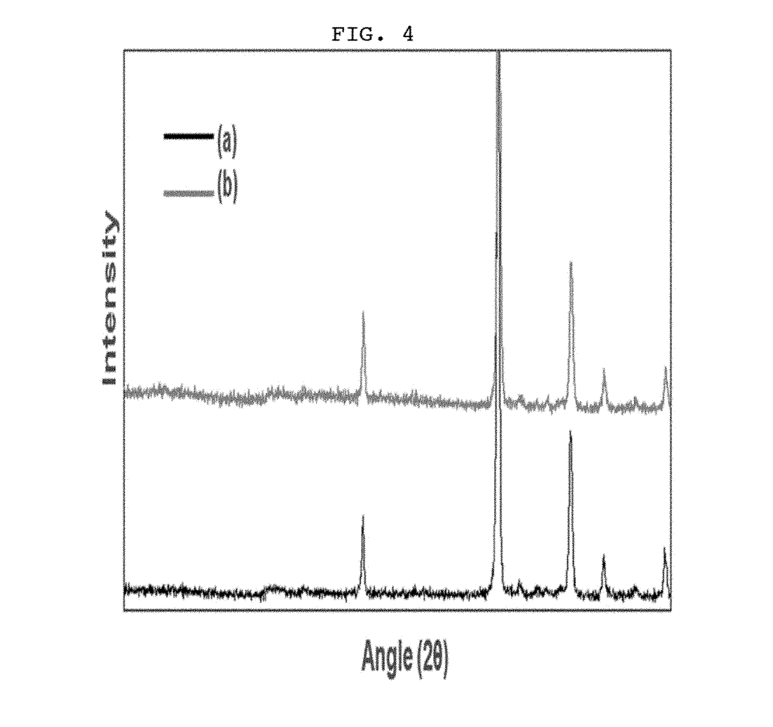

In addition, the coating film fabricated in the Embodiment 1 was analyzed in terms of XRD and EDS (JEOL 6001) to identify its composition and crystalline phases before, (a), and after, (b), the hydration of the coating film. The results are shown in FIGS. 3(a), 3(b) and 4. As shown in FIGS. 3(a), 3(b), and 4, it is verified the coating film fabricated in the Embodiment 1 does not show any change of its composition and crystalline phases after being hydrated.

### Embodiment 2

The plasma resistant coating film was fabricated according to the same method as employed in the Embodiment 1 with the addition of the second rare earth metal compound layer formed by using YOF particles.

### Comparative Example 1

The coating film was fabricated according to the same method as employed in the Embodiment 1 save for the hydration treatment.

### Comparative Example 2

As in the Embodiment 1-1, the first rare earth metal compound layer was formed on an aluminum plate; the aluminum plate on which the first rare earth metal compound layer was formed was washed with deionized water; the aluminum plate was dried at 100° C. for 3 hours; and the aluminum plate was wetting-treated by being submerged in deionized water at 90° C. for 5 hours. The wetting-treated aluminum plate was dried in vacuum at 100° C. for 5 hours. The wetting and drying-in-vacuum treatment were repeated under the same conditions 5 times to hydrate the aluminum plate on which the first rare earth metal compound layer was formed.

The second rare earth metal compound layer with a thickness of 10 μm was formed, to fabricate the coating film on the aluminum plate, by aerosolizing yttria (Y₂O₃) particles by using a particle vibrator in an aerosol chamber maintained in vacuum atmosphere at ambient temperature and then physically colliding at about 300 m/s the aerosolized yttria particles together with Ar gas onto the hydrated first rare earth metal compound layer by using the pressure difference between the aerosol chamber and a deposition chamber.

### Comparative Example 3

The second rare earth metal compound layer with a thickness of 10 μm was formed on the aluminum plate by aerosolizing yttria (Y₂O₃) particles by using a particle vibrator in an aerosol chamber maintained in vacuum atmosphere and then physically colliding at about 300 m/s the aerosolized yttria particles together with Ar gas onto the aluminum plate of 5 cm×5 cm×0.5 cm by using the pressure difference between the aerosol chamber and a deposition chamber.

The aluminum plate on which the second rare earth metal compound layer was formed was washed with deionized water; the aluminum plate was dried at 100° C. for 3 hours; and the aluminum plate was wetting-treated by being submerged in deionized water at 90° C. for 5 hours. The wetting-treated aluminum plate was dried in vacuum at 100° C. for 3 hours. The wetting and drying-in-vacuum treatment were repeated under the same conditions 5 times to form a single coating film that is only the hydrated second rare earth metal compound layer formation. However, the coating film was detached and the experiment described below could not be performed.

### Comparative Example 4

The coating film was fabricated according to the method of the Embodiment 2 save for the hydration treatment.

### Comparative Example 5

The coating film was fabricated according to the same method of the Embodiment 2, where YOF particles instead of yttria were selected as the second rare earth metal compound.

### Comparative Example 6

The coating film was fabricated according to the same method of the Embodiment 3, where YOF particles instead of yttria were selected as the second rare earth metal compound. However, the coating film formed on the aluminum plate was detached and the experiment described below could not be performed.

The coating films fabricated in the Embodiments 1 and 2 and the Comparative Examples 1 through 6 were characterized, whose results are listed in Table 1.

### Experimental Example 1

Surface roughness values (μm) of the coating films fabricated in the Embodiments and the Comparative Examples of the present disclosure were measured with a roughness measuring device (SJ-201), whose results are listed in Table 1.

TABLE 1

| | Surface roughness (μm) | |
|---|---|---|
| | The first rare earth | The second rare earth |
| | metal compound layer | metal compound layer |
| Embodiment 1 | 2.5 | 2.8 |
| Embodiment 2 | 2.7 | 2.7 |
| Comparative Ex. 1 | 2.5 | 2.9 |
| Comparative Ex. 2 | 2.5 | 2.8 |
| Comparative Ex. 4 | 2.7 | 2.8 |
| Comparative Ex. 5 | 2.7 | 2.8 |

As shown in Table 1, the surface roughness did not change after the wetting treatment.

### Experimental Example 2

Hardness values (Hv) of the coating films fabricated in the Embodiments and the Comparative Examples of the present disclosure were measured with a Vickers hardness tester (KSB0811), whose results are listed in Tables 2 and 3.

TABLE 2

| | Hardness (Hν) |
|---|---|
| Embodiment 1 | 517 |
| Comparative Ex. 1 | 434 |
| Comparative Ex. 2 | 452 |

TABLE 3

| | Hardness(Hν) |
|---|---|
| Embodiment 2 | 398 |
| Comparative Ex. 4 | 314 |
| Comparative Ex. 5 | 327 |

As listed in Tables 2 and 3, the Embodiment 1 showed hardness values higher than those of the Comparative Examples 1 through 3 while the Embodiment 2 showed hardness values higher than those of the Comparative Examples 4 through 6. However, the Embodiment 2 was lower than the Embodiment 1 in terms of hardness. It is thought that it was because the yttria used in the Embodiment 1 and the YOF used in the Embodiment 2 were different from each other in terms of their physical properties.

### Experimental Example 3

Porosity values (vol %) of the coating films fabricated in the Embodiments and the Comparative Examples of the present disclosure were measured with an SEM (JEOL 6001, cross-sectional X300), whose results are listed in Tables 4 and 5.

TABLE 4

| | Porosity (vol %) | |
|---|---|---|
| | The first rare earth | The second rare earth |
| | metal compound layer | metal compound layer |
| Embodiment 1 | 5.31 | 1.10 |
| Comparative Ex. 1 | 9.56 | 5.58 |
| Comparative Ex. 2 | 5.27 | 5.49 |

TABLE 5

| | Porosity (vol %) | |
|---|---|---|
| | The first rare earth | The second rare earth |
| | metal compound layer | metal compound layer |
| Embodiment 2 | 4.84 | 0.87 |
| Comparative Ex. 4 | 8.24 | 5.43 |
| Comparative Ex. 5 | 5.15 | 5.39 |

As shown in Tables 4 and 5, the Embodiment 1 was lower than the Comparative Examples 1 and 2 while the Embodiment 2 was lower than the Comparative Examples 4 and 5 in terms of porosity. However, the Embodiment 2 was lower than the Embodiment 1 in terms of porosity. It is thought it was because the yttria used in the Embodiment 1 and the YOF used in the Embodiment 2 were different from each other in terms of their physical properties.

### Experimental Example 4

Electrical resistance values (0 cm) of the coating films fabricated in the Embodiments and the Comparative Examples of the present disclosure were measured with a resistance meter (4339B high), whose results are listed in Tables 6 and 7.

TABLE 6

| | Electrical resistance (Ω cm) |
|---|---|
| Embodiment 1 | 3.15 × 10¹³ |
| Comparative Ex. 1 | 2.98 × 10¹¹ |
| Comparative Ex. 2 | 9.24 × 10¹¹ |

TABLE 7

| | Electrical resistance (Ω cm) |
|---|---|
| Embodiment 2 | 2.91 × 10¹³ |
| Comparative Ex. 4 | 2.66 × 10¹¹ |
| Comparative Ex. 5 | 8.89 × 10¹¹ |

As shown in Tables 6 and 7, the Embodiment 1 was lower than the Comparative Examples 1 and 2 while the Embodiment 2 was lower than the Comparative Examples 4 and 5 in terms of electrical resistance. However, the Embodiment 2 was lower than the Embodiment 1 in terms of electrical resistance. It is thought it was because the yttria used in the Embodiment 1 and the YOF used in the Embodiment 2 were different from each other in terms of their physical properties.

### Experimental Example 5

Etch rate values (μm) of the coating films fabricated in the Embodiments and the Comparative Examples of the present disclosure were measured with Unaxis, VLICP (Etching: CF₄/O₂/Ar, Flow Rate: 30/5/10 Sccm, Chamber Pressure: 0.1 torr, Power: Top-0700 W, Bottom 250 W) for 2 hours, whose results are listed in Tables 8 and 9.

TABLE 8

| | Etch rate (μm) |
|---|---|
| Embodiment 1 | 0.714 |
| Comparative Ex. 1 | 1.041 |
| Comparative Ex. 2 | 1.009 |

TABLE 9

| | Etch rate (μm) |
|---|---|
| Embodiment 2 | 0.729 |
| Comparative Ex. 4 | 1.88 |
| Comparative Ex. 5 | 1.071 |

As shown in Tables 8 and 9, the Embodiment 1 was lower than the Comparative Examples 1 and 2 while the Embodiment 2 was lower than the Comparative Examples 4 and 5 in terms of etch rate. However, the Embodiment 2 was higher than the Embodiment 1 in terms of etch rate. It is thought it was because the yttria used in the Embodiment 1 and the YOF used in the Embodiment 2 were different from each other in terms of their physical properties

### Experimental Example 6

Ink impregnation properties of the coating films fabricated in the Embodiment 1 and the Comparative Example 1 of the present disclosure was analyzed. For characterizing, the coating films were taken off the aluminum plates and submerged for 10 minutes in a mixed solution of deionized water and water-soluble ink, whose results are listed in Table 5.

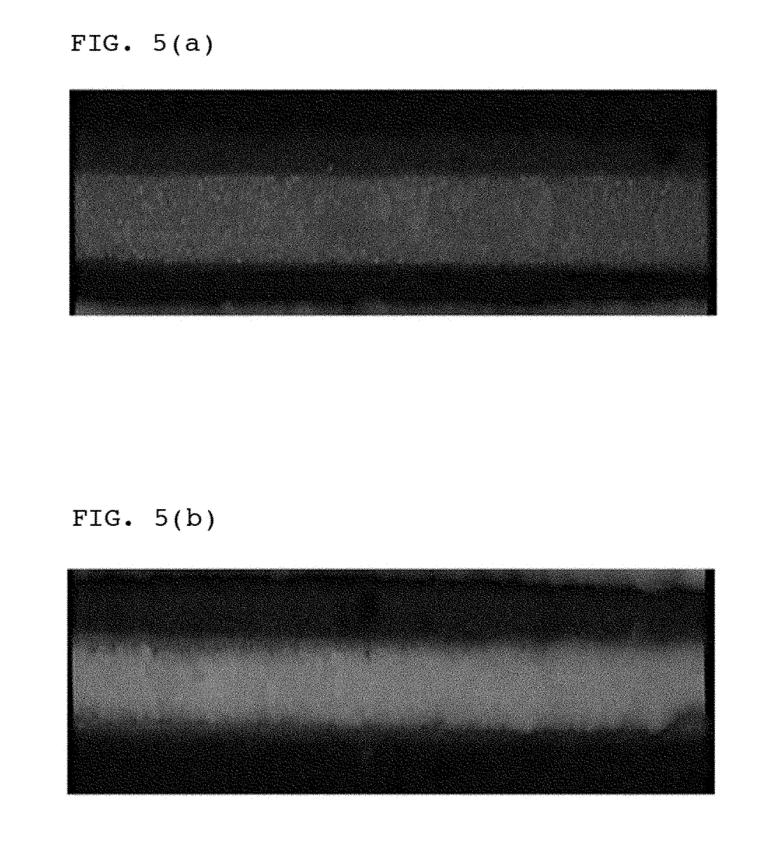

As shown in FIGS. 5(a) and 5(b), the coating film fabricated in the Embodiment 1 (FIG. 5(a)) was lower than that fabricated in the Comparative Example 1 (FIG. 5(b)) in terms of ink impregnation, which verifies the open channels and cracks in the coating film fabricated in the Embodiment 1 were stably filled in.

The present disclosure can be simply changed or modified by a person skilled in the art and such change or modification should be regarded as being included in the scope of right of the present disclosure.

1. A fabricating method of a plasma resistant coating film, comprising:
(a) a step of forming a first rare earth metal compound layer by thermally spraying a first rare earth metal compound on an object of coating;
(b) a step of forming a second rare earth metal compound layer by aerosol-depositing a second rare earth metal compound on the formed first rare earth metal compound layer; and
(c) a step of hydrating the formed first and second rare earth metal compounds

2. The fabricating method of a plasma resistant coating film of claim 1, wherein the first rare earth metal compound is one or more species selected from a group of Y₂O₃, Dy₂O₃, Er₂O₃, Sm₂O₃, YAG, YOF and YF.

3. The fabricating method of a plasma resistant coating film of claim 1, wherein the first rare earth metal compound layer has a thickness of 100 to 300 μm.

4. The fabricating method of a plasma resistant coating film of claim 1, wherein the step of (c) hydrating comprises:
(i) a step of washing the formed first and second rare earth metal compound layers;
(ii) a step of drying the washed first and second rare earth metal compound layers;
(iii) a step of wetting the dried first and second rare earth metal compound layers; and
(iv) a step of vacuum-baking the wet first and second rare earth metal compound layers.

5. The fabricating method of a plasma resistant coating film of claim 4, wherein the wetting treatment is performed at 60 to 120° C. for 1 to 48 hours.

6. The fabricating method of a plasma resistant coating film of claim 4, wherein the hydrating repeats the steps (iii) and (iv) twice or more.

7. The fabricating method of a plasma resistant coating film of claim 1, wherein the second rare earth metal compound is one or more species selected from a group of Y₂O₃, Dy₂O₃, Er₂O₃, Sm₂O₃, YAG, YOF and YF.

8. The fabricating method of a plasma resistant coating film of claim 1, wherein the second rare earth metal compound coating layer has a thickness of 5 to 30 μm.

9. The fabricating method of a plasma resistant coating film of claim 1, wherein the first rare earth metal compound coating layer has a porosity of 10 vol % or less after the step (c).

10. The fabricating method of a plasma resistant coating film of claim 1, wherein the second rare earth metal compound coating layer has a porosity of 5 vol % or less after the step (c).

11. The plasma resistant coating film fabricated by the method of claim 1, comprising:
the first rare earth metal compound layer which is formed by thermally spraying the first rare earth metal compound and hydrating the compound; and
the second rare earth metal compound layer which is formed by aerosol-depositing the second rare earth metal compound on the first rare earth metal compound layer and hydrating the compound.

12. The plasma resistant coating film of claim 11, wherein the first rare earth metal compound is one or more species selected from a group of Y₂O₃, Dy₂O₃, Er₂O₃, Sm₂O₃, YAG, YOF and YF.

13. The plasma resistant coating film of claim 11, wherein the second rare earth metal compound is one or more species selected from a group of Y₂O₃, Dy₂O₃, Er₂O₃, Sm₂O₃, YAG, YOF and YF.

14. The plasma resistant coating film of claim 11, wherein the first rare earth metal compound layer has a thickness of 100 to 300 μm.

15. The plasma resistant coating film of claim 11, wherein the second rare earth metal compound coating layer has a thickness of 5 to 30 μm.

16. The plasma resistant coating film of claim 11, wherein the first rare earth metal compound coating layer has a porosity of 10 vol % or less.

17. The plasma resistant coating film of claim 11, wherein the second rare earth metal compound coating layer has a porosity of 5 vol % or less.
